(19) United States
(12) Patent Application Publication
(10) Pub. No.: US 2016/0168699 A1
(43) Pub. Date: Jun. 16, 2016

(54) METHOD FOR DEPOSITING METAL-CONTAINING FILM USING PARTICLE-REDUCTION STEP

(71) Applicant: ASM IP Holding B.V., Almere (NL)

(72) Inventors: Atsuki Fukazawa, Tokyo (JP); Hideaki Fukuda, Tokyo (JP)

(21) Appl. No.: 14/568,647

(22) Filed: Dec. 12, 2014

(51) Int. Cl. C23C 16/44; C23C 16/34; C23C 16/40; C23C 16/505; C23C 16/455

(52) U.S. Cl. CPC C23C 16/4402; C23C 16/505; C23C 16/4554; C23C 16/45553; C23C 16/405; C23C 16/40; C23C 16/34

(57) ABSTRACT

A method for forming a metal oxide or nitride film on a substrate by plasma-enhanced atomic layer deposition (PEALD), includes: introducing an amino-based metal precursor in a pulse to a reaction space where a substrate is placed, using a carrier gas; and continuously introducing a reactant gas to the reaction space; applying RF power in a pulse to the reaction space wherein the pulse of the precursor and the pulse of RF power do not overlap, wherein conducted is at least either step (a) comprising passing the carrier gas through a purifier for reducing impurities before mixing the carrier gas with the precursor, or step (b) introducing the reactant gas at a flow rate such that a partial pressure of the reactant gas relative to the total gas flow provided in the reaction space is 15% or less.

### BACKGROUND OF THE INVENTION

1. Field of the Invention

The present invention generally relates to a method for depositing a film containing a metal such as a transition metal without increasing particle contamination.

2. Description of the Related Art

It is well known that a process material for forming a film containing Zr or Ti has strong reactivity to moisture or air. Thus, the process material is difficult to handle and causes a problem associated with the presence of a small amount of oxidizing component. For example, when forming a ZrO film by CVD, particles tend to be generated due to co-existence of a process material and an oxidizing gas. If particle generation is a problem in the process, it is required to control the co-existence state of the process material and the oxidizing gas by adjusting the location of gas inlets, method of introducing the gases, etc. Also in atomic layer deposition (ALD), particle generation is a problem unavoidable when a process material and an oxidizing gas co-exist in the process. For example, oxygen gas used as a reactant gas contacts a precursor used as a process material, generating particles. As with an oxidizing gas, reactivity of a reactant gas used for nitridization against a precursor tends to cause a similar particle-generation problem. In order to avoid encountering the problem, a process sequence may be adjusted so that a process material and a reactant gas do not co-exist in the process. However, such modifications of the sequence prolong the cycle duration, lowering productivity.

Any discussion of problems and solutions in relation to the related art has been included in this disclosure solely for the purposes of providing a context for the present invention, and should not be taken as an admission that any or all of the discussion was known at the time the invention was made.

### SUMMARY OF THE INVENTION

Some embodiments provide a method for forming a metal oxide or nitride film on a substrate by plasma-enhanced atomic layer deposition (PEALD), which method can solve at least one of the above-discussed problems, e.g., a particle-generation problem, without separating a precursor and a reactant gas in a reaction space during a film formation process, even when the precursor and the reactant gas are highly reactive to each other (e.g., having reactivity equivalent to or more than that between tetrakis-dimethyl-amino-V and oxygen or ammonia). In some embodiments, as a particle-reduction step, at least one of the following is performed: (1) the process temperature is adjusted in a range of 0° C. to 250° C., (2) the partial pressure of a reactant gas is adjusted in a range of 15% or less relative to the total gas pressure in a reaction space, and (3) the amount of impurities such as moisture contained in a reactant gas is adjusted in a range of 10 ppb or less. Steps (1) and (2) significantly contribute to particle reduction, and if steps (1) and (2) are not satisfied, the number of particles having a size of 0.1 μm or greater which are generated during a film-forming process may reach 500 to 100,000 per substrate under some circumstances. Step (3) also is important, and if step (3) is not satisfied, a precursor may react with a small amount of impurities such as moisture contained in a reactant gas, generating particles during a film-forming process. When one or more of steps (1) to (3) are performed, the film-forming process can be stabilized without generating a substantial number of particles (e.g., less than 500 per substrate). Further, when the process temperature is controlled at a low temperature, and the reactant gas is controlled at a low concentration, crystalline grains constituting a film can effectively be controlled, e.g., controlling crystalline, amorphous, or mixed state of grains, and controlling a surface roughness of a film (e.g., lowering a surface roughness to about 0.1 nm or less). Additionally, even when step (2) is performed, i.e., lowering partial pressure of a reactant gas, since reactivity between the precursor and the reactant gas is high, a film can sufficiently undergo oxidization or nitridization, exhibiting sufficient chemical resistance and mechanical strength. Further, since the precursor and the reactant gas are not separated or the reactant gas flows continuously, the process sequence can be simplified, improving productivity.

Additionally, thermal stability of a precursor in view of its chemical structure is important to reduction of particles generated during a film-forming process. For example, the higher the molecular size of a terminal group (referred to as reactive group), the further the improvement on thermal stability of the precursor becomes, and thus, when the precursor has a reactive group having a molecular weight equivalent to or higher than e.g., —N(CH₃)₂, the reactive group of the precursor is not easily dissociated from the precursor when contacting an oxidizing gas, further contributing to a reduction of particles. Thus, by selecting a suitable precursor and setting a process temperature, a reactant gas can flow continuously while suppressing generation of particles.

For purposes of summarizing aspects of the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description which follows.

### BRIEF DESCRIPTION OF THE DRAWINGS

These and other features of this invention will now be described with reference to the drawings of preferred embodiments which are intended to illustrate and not to limit the invention. The drawings are greatly simplified for illustrative purposes and are not necessarily to scale.

FIG. 1 is a schematic representation of a PEALD (plasma-enhanced atomic layer deposition) apparatus for depositing a dielectric film usable in an embodiment of the present invention.

FIG. 2 shows a schematic process sequence of PEALD in one cycle according to an embodiment of the present invention wherein a step illustrated in a column represents an ON state whereas no step illustrated in a column represents an OFF state, and the width of each column does not represent duration of each process.

FIG. 3 shows a schematic process sequence of PEALD in one cycle according to a comparative embodiment wherein a step illustrated in a column represents an ON state whereas no step illustrated in a column represents an OFF state, and the width of each column does not represent duration of each process.

FIG. 4A is a schematic representation of a gas supply system for a reactant gas according to an embodiment of the present invention.

FIG. 4B is a schematic representation of a gas supply system for a reactant gas according to an embodiment of the present invention.

FIG. 4C is a schematic representation of a flow-pass system for a precursor according to an embodiment of the present invention.

FIG. 5A is a schematic representation of a flow-pass system for a liquid material usable in an embodiment of the present invention.

FIG. 5B is a schematic representation of the flow-pass system when a carrier gas carries a vaporized precursor from a bottle and flows with the precursor to a reaction chamber.

FIG. 5C is a schematic representation of the flow-pass system when a carrier gas bypasses the bottle and flows without the precursor to the reaction chamber.

### DETAILED DESCRIPTION OF EMBODIMENTS

In this disclosure, “gas” may include vaporized solid and/or liquid and may be constituted by a single gas or a mixture of gases. In this disclosure, a process gas introduced to a reaction chamber through a showerhead may be comprised of, consist essentially of, or consist of a metal-containing precursor and an additive gas. The additive gas typically includes a reactant gas for oxidizing and/or nitridizing the precursor when RF power is applied to the additive gas. The reactant gas may be diluted with a dilution gas which is introduced to the reaction chamber as a mixed gas with the reactant gas or separately from the reactant gas. The precursor can be introduced with a carrier gas such as a rare gas. Also, a gas other than the process gas, i.e., a gas introduced without passing through the showerhead, may be used for, e.g., sealing the reaction space, which includes a seal gas such as a rare gas. In some embodiments, the term “precursor” refers generally to a compound that participates in the chemical reaction that produces another compound, and particularly to a compound that constitutes a film matrix or a main skeleton of a film, whereas the term “reactant” refers to a compound that activates a precursor, modifies a precursor, or catalyzes a reaction of a precursor. The term “precursor” refers to a vaporized or gaseous precursor without a carrier gas, or a carrier gas containing a vaporized or gaseous precursor, depending on the context. Similarly, the term “reaction gas” refers to a reaction gas without a dilution gas, or a reaction gas diluted with a dilution gas, depending on the context. In some embodiments, “film” refers to a layer continuously extending in a direction perpendicular to a thickness direction substantially without pinholes to cover an entire target or concerned surface, or simply a layer covering a target or concerned surface. In some embodiments, “layer” refers to a structure having a certain thickness formed on a surface or a synonym of film or a non-film structure. A film or layer may be constituted by a discrete single film or layer having certain characteristics or multiple films or layers, and a boundary between adjacent films or layers may or may not be clear and may be established based on physical, chemical, and/or any other characteristics, formation processes or sequence, and/or functions or purposes of the adjacent films or layers. Further, in this disclosure, any two numbers of a variable can constitute a workable range of the variable as the workable range can be determined based on routine work, and any ranges indicated may include or exclude the endpoints. Additionally, any values of variables indicated (regardless of whether they are indicated with “about” or not) may refer to precise values or approximate values and include equivalents, and may refer to average, median, representative, majority, etc. in some embodiments.

Additionally, the terms “constituted by” and “having” refer independently to “typically or broadly comprising”, “comprising”, “consisting essentially of”, or “consisting of” in some embodiments. Further, an article “a” or “an” refers to a species or a genus including multiple species. In this disclosure, any defined meanings do not necessarily exclude ordinary and customary meanings in some embodiments.

In the present disclosure where conditions and/or structures are not specified, the skilled artisan in the art can readily provide such conditions and/or structures, in view of the present disclosure, as a matter of routine experimentation. In all of the disclosed embodiments, any element used in an embodiment can be replaced with any elements equivalent thereto, including those explicitly, necessarily, or inherently disclosed herein, for the intended purposes. Further, the present invention can equally be applied to apparatuses and methods.

The embodiments will be explained with respect to preferred embodiments. However, the present invention is not limited to the preferred embodiments.

In some embodiments, a method for forming a metal oxide or nitride film on a substrate by plasma-enhanced atomic layer deposition (PEALD), comprises: (i) introducing an amino-based metal precursor in a pulse to a reaction space where a substrate is placed, using a carrier gas; (ii) continuously introducing a reactant gas to the reaction space; (iii) applying RF power in a pulse to the reaction space wherein the pulse of the precursor and the pulse of RF power do not overlap; and (iv) repeating steps (i) to (iii) to deposit a metal oxide or nitride film on the substrate, wherein at least one particle-reduction step is conducted in step (i) and/or step (ii), said at least one particle-reduction step being selected from step (a) comprising passing the carrier gas through a purifier for reducing impurities contained in the carrier gas, and then mixing the carrier gas with a gas of the precursor upstream of the reaction space in step (i); and step (b) introducing the reactant gas to the reaction space in step (ii) at a flow rate such that a partial pressure of the reactant gas relative to the total gas flow provided in the reaction space is 15% or less. Impurities are unwanted substances which are detected in a gas at issue and which prevent it from being pure.

In some embodiments, step (a) is conducted as the at least one particle-reduction step wherein the impurities include H₂O, and O₂, CO₂, and/or CO if any. In some embodiments, the impurities contained in the carrier gas are reduced to 10 ppb or less (preferably 1 ppb or less). As a purifier, any suitable gas purifier can be used, including any conventional purifier, as long as the purifier can stably purify a passing gas to a desired degree, regardless of purifying mechanisms. For example, a purifier disclosed in U.S. Pat. No. 7,465,692 can be used, the disclosure of which is hereby incorporated by reference in its entirety in some embodiments. To be specific, a Gas Clean ST Purifier assembly (by Pall Corporation) can be used in some embodiments, which uses a chemical adsorbent combined with a stainless steel filter media and is designed to remove contamination from many process gases, wherein sub ppb level purification is achieved at designed flow rates of up to 5 slm while providing 0.003 μm filtration. The concentration of impurities contained in a gas after passing through a purifier can be determined according to technical information or test results available for the purifier from the manufacturer, without actually measuring the concentration of impurities.

In some embodiments, step (ii) further comprises passing the reactant gas through a purifier for reducing impurities contained in the reactant gas before introducing the reactant gas to the reaction space. A purifier for the reactant gas can be the same as that for the carrier gas in some embodiments. In some embodiments, the reactant gas passes through a mass flow controller, wherein the purifier is provided upstream of the mass flow controller. In some embodiments, step (ii) further comprises introducing to the reaction space a dilution gas for diluting the reaction gas, wherein the dilution gas passes through a purifier for reducing impurities contained in the dilution gas before entering into the reaction space. A purifier for the dilution gas can be the same as that for the carrier gas in some embodiments. In some embodiments, all of the gases introduced to the reaction space pass through purifiers, respectively, except that a precursor after being mixed with a carrier gas does not pass through a purifier upstream of the reaction space because the carrier gas has passed through a purifier before mixing with the vaporized or gaseous precursor, and the precursor is reactive and may be removed by a purifier.

In some embodiments, step (b) is conducted as the at least one particle-reduction step, wherein the partial pressure of the reactant gas relative to the total gas flow provided in the reaction space is controlled at 15% or less (e.g., less than 12%, less than 5%). The partial pressure of the reactant gas can be calculated as follows, for example. If the flow rates of a carrier gas, dilution gas, reactant gas, and seal gas are 2 slm, 0.5 slm, 0.1 slm, and 0.2 slm, respectively, the total gas flow provided in the reaction space is 2.7 slm, and thus, the partial pressure of the reactant gas is calculated at 3.7% (0.1 slm/2.7 slm=3.7%). In the above, the carrier gas carries vaporized or gaseous precursor in a range of about 0.001 g/pulse to about 1 g/pulse, which may correspond to about 10 sccm, to the reaction space. However, the flow rate of the carrier gas is predominant as compared with a portion of the precursor itself, and after the carrier gas mixes with the precursor, the carrier gas does not pass through a mass flow controller, and accurate measurement of the portion of the precursor is difficult. Thus, it can be considered that the flow rate of the carrier gas, which is measured at a mass flow controller before mixing with the vaporized or gaseous precursor, represents the flow rate of the carrier gas including the precursor and is substantially equivalent to the flow rate of the carrier gas including the precursor. Alternatively, it also can be considered that the flow rate of the carrier gas, which is measured at a mass flow controller before mixing with the vaporized or gaseous precursor, plus 10 sccm, which is considered to represent the flow rate of the precursor, represents the flow rate of the carrier gas including the precursor and is substantially equivalent to the flow rate of the carrier gas including the precursor. In the above, if the flow rate of the carrier gas including the precursor is 2.01 slm, instead of 2 slm, the partial pressure of the reactant gas is calculated at 3.69%, instead of 3.70% (both 3.7% when rounded off to one decimal place), and thus, unless the flow of the precursor itself is significant, the partial pressure of the reactant can be calculated using the flow rate of the carrier gas in place of the flow rate of the carrier gas including the vaporized or gaseous precursor.

If step (a) is conducted without step (b), the partial pressure of the carrier gas need not be 15% or less, and can be 17% or higher, or 19% or higher, depending on the type of reactant gas. In some embodiments, both steps (a) and (b) are conducted as the at least one particle-reduction step.

In some embodiments, the carrier gas is an inert gas, e.g., a rare gas (noble gas) such as He, Ne, Ar, Kr, and/or Xe, preferably Ar and/or He. The dilution gas can be the same as the carrier gas. In some embodiments, the reactant gas is at least one oxidizing gas selected from the group consisting of O₂, N₂O, CO₂, NxOyHz, and CxOyHz wherein x, y, and z are each an integer, for forming a metal oxide film on the substrate. In some embodiments, the reactant gas is at least one nitridizing gas selected from the group consisting of NH₃, N₂/H₂, and N₂ for forming a metal nitride film on the substrate. In some embodiments, the nitridizing gas can additionally or alternatively be selected from a gas of CxHyNz wherein x, y, and z are each an integer with the proviso that if x is zero, y and z are not zero, and if z is zero, x and y are not zero, and in some embodiments, either x or z is zero. In some embodiments, CxHyNz includes a hydrocarbon CxHy (z is zero) (non-cyclic or cyclic) such as C₆H₁₄ and C₆H₁₂, and a nitrogen hydride HyNz (x is zero) such as N₂H₄ and HN₃. In some embodiments, x is 0 to 10 (preferably 1 to 6), y is 2 to 20 (preferably 1 to 5), and z is 0 to 3 (preferably 0 to 2).

In some embodiments, the amino-based metal precursor is at least one selected from the group consisting of:

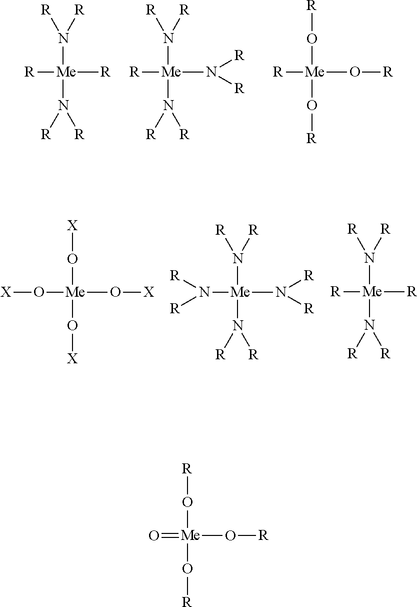

wherein R is independently H, CxHy, CxHyOz, CS, or CO (wherein x, y, and z are each an integer), X is independently H, CxHy, or CxHyOz (wherein x, y, and z are each an integer), and Me is a metal.

In some embodiments, the metal is a transition element, and preferably, the metal is selected from the groups consisting of Zr, Ti, Hf, Ta, Ir, V, and Ce. Thermal stability of a precursor in view of its chemical structure is important to reduction of particles generated during a film-forming process. For example, the higher the molecular size of a terminal group (referred to as reactive group), the greater the improvement on thermal stability of the precursor becomes, and thus, when the precursor has a reactive group such as cyclopentadienyl (C₅H₅) having a molecular weight equivalent to or higher than e.g., —N(CH₃)₂, the reactive group of the precursor is not easily dissociated from the precursor when contacting an oxidizing gas, further contributing to a reduction of particles. In some embodiments, the precursor is tris(dimethyl-amino)-cyclopentadienyl-Zr, tris(dimethyl-amino)-cyclopentadienyl-Hf, and/or tetrakis(dimethyl-amino)-V.

In some embodiments, the reaction space is controlled at a temperature of 0° C. to 250° C. (typically 150° C. to 250° C.). If the process temperature is higher than 250° C., the precursor tends to decompose, causing particle generation. In some embodiments, the gas of the precursor before being mixed with the carrier gas is a vapor of the precursor having a pressure of 0.1 to 5 Torr (e.g., 0.5 to 3 Torr).

In some embodiments, the carrier gas is continuously introduced to the reaction space wherein the precursor is mixed with the carrier gas in a pulse in step (i). This can be accomplished by using a flow-pass system for a liquid precursor, wherein the carrier gas enters into a top portion of a bottle containing a liquid precursor and its vapor in the top portion of the bottle, passes through the top portion, flows out of the bottle with a vaporized precursor, and flows into the reaction space while carrying the vaporized precursor, or the carrier gas bypasses the bottle and flows to the reaction space without a vaporized precursor. By continuously introducing the carrier gas, efficiency of purging can be improved, and also pressure fluctuation can be minimized, stabilizing the process and suppressing particle generation. In the above, “continuously” refers to without interruption as a timeline, typically at a constant flow rate. Similarly, also as with the reactant gas, the dilution gas is continuously introduced to the reaction space.

In some embodiments, the number of particles having a size of 0.1 μm or more present on the metal oxide or nitride film on the substrate is less than 500, preferably less than 100 or less than 25. The number of particles can be measured using a particle detection device such as SP1 (by KLA Tencor).

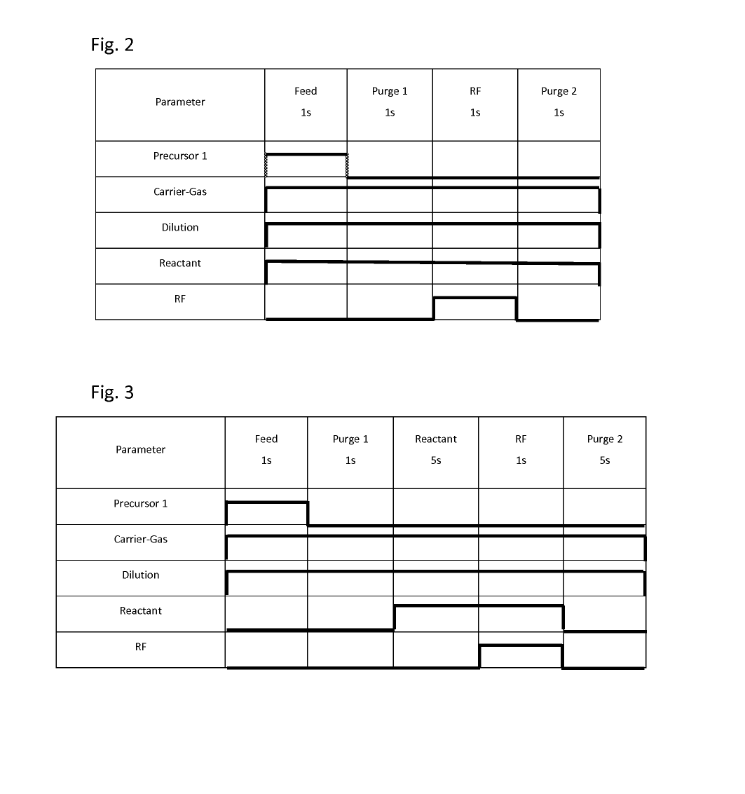

In some embodiments, the process sequence may be set as illustrated in FIG. 2. FIG. 2 shows a schematic process sequence of PEALD in one cycle according to an embodiment of the present invention wherein a step illustrated in a column represents an ON state whereas no step illustrated in a column represents an OFF state, and the width of each column does not represent duration of each process. In this embodiment, one cycle of PEALD consists of “Feed” where a precursor is fed to a reaction space via a carrier gas which carries the precursor without applying RF power to the reaction space, and also, a dilution gas and a reactant gas are fed to the reaction space, thereby chemisorbing the precursor onto a surface of a substrate via self-limiting adsorption; “Purge 1” where no precursor is fed to the reaction space, while the carrier gas, dilution gas, and reactant gas are continuously fed to the reaction space, without applying RF power, thereby removing non-chemisorbed precursor from the surface of the substrate; “RF” where RF power is applied to the reaction space while the carrier gas, dilution gas, and reactant gas are continuously fed to the reaction space, without feeding the precursor, thereby forming an atomic layer from the chemisorbed precursor through plasma reaction with the reactant gas; and “Purge 2” where the carrier gas, dilution gas, and reactant gas are continuously fed to the reaction space, without feeding the precursor and without applying RF power to the reaction space, thereby removing unreacted precursor and reactant gas from the surface of the substrate. In the above, in the “Feed” step, the precursor and the reaction gas co-exist in the reaction space, and thus, without any of the particle-reduction steps according to embodiments of the present invention, a substantial number of particles is generated during the film-forming process. Incidentally, in this embodiment, the durations of the Feed step, the Purge 1 step, the RF step, and the Purge 2 step are all one second, and thus, the total duration of one cycle is 4 seconds.

FIG. 3 shows a schematic process sequence of PEALD in one cycle according to a comparative embodiment wherein a step illustrated in a column represents an ON state whereas no step illustrated in a column represents an OFF state, and the width of each column does not represent duration of each process. In this comparative embodiment, one cycle of PEALD consists of “Feed”, “Purge 1”, “Reactant”, “RF”, and “Purge 2”. The differences between the sequence illustrated in FIG. 2 and that illustrated in FIG. 3 are: the precursor and the reactant gas are separated from each other during the film-forming process, so that particle generation can be avoided. That is, in the Feed step, the Purge 1, and the Purge 2 step, no reactant gas is fed to the reaction space. In the Reactant step, the reactant gas is fed to the reaction space while continuously feeding the carrier gas and the dilution gas, without feeding the precursor and without applying RF power, and in the RF step, the reactant gas is continuously fed to the reaction space and RF power is applied to the reaction space, while continuously feeding the carrier gas and the dilution gas without feeding the precursor. When the reaction gas is fed in the Reactant step, non-chemisorbed precursor has been removed from the surface of the substrate, and thus, no unwanted reaction occurs, and particle generation can be suppressed. However, in this comparative embodiment, the durations of the Feed step, the Purge 1 step, the Reactant step, the RF step, and the Purge 2 step are one second, one second, five seconds, one second, and five seconds, and thus, the total duration of one cycle is 13 seconds, which is more than 3 times longer than the duration of the cycle illustrated in FIG. 2 according to an embodiment of the present invention.

In some embodiments, PEALD may be conducted under conditions shown in Table 1 below.

TABLE 1
Conditions

| | |
|---|---|
| Substrate temperature | 0 to 250° C. (preferably 100 to 200° C.) |
| Pressure | 133 to 800 Pa (preferably 200 to 600 Pa) |
| Reactant | O₂, N₂O, CO₂, NxOyHz, CxOyHz; NH₃, N₂/H₂, N₂, H₂, |
| | and CxHyNz |
| Flow rate of reactant (continuous) | 10 to 1000 sccm (preferably 50 to 500 sccm) |
| Dilution gas (rare gas) | He, Ar |
| Flow rate of dilution gas | 100 to 6000 sccm (preferably 500 to 2000 sccm) |
| (continuous) | |
| Concentration (partial pressure) of | 3 to 19% (preferably 4 to 11%) |
| reactant | |
| Precursor | Tris(dimethyl-amino)-cyclopentadienyl-Zr, |
| | Tris(dimethyl-amino)-cyclopentadienyl-Hf, |
| | Tetrakis(dimethyl-amino)-V |
| Flow rate of precursor (including | 1000 to 6000 sccm (preferably 1500 to 4000 sccm) |
| carrier gas) | |
| Precursor pulse (supply time of the | 0.1 to 5 sec (preferably 0.1 to 1 sec) |
| gas) | |
| Purge upon the precursor pulse | 0.1 to 10 sec (preferably 0.2 to 2 sec) |
| RF power (13.56 MHz) for a 300-mm | 20 to 500 W (preferably 50 to 200 W) |
| wafer | |
| RF power pulse | 0.1 to 10 sec (preferably 0.2 to 5 sec) |
| Purge upon the RF power pulse | 0.1 to 3 sec (preferably 0.1 to 1 sec) |
| Thickness of film | 3 to 30 nm (preferably 5 to 25 nm) |

In the above, N₂/H₂ refers to a mixture of N₂ and H₂, and a mixing rate of N₂ to H₂ is 10:1 to 1:10 (preferably 1:5 to 5:1). Since ALD is a self-limiting adsorption reaction process, the amount of deposited precursor molecules is determined by the number of reactive surface sites and is independent of the precursor exposure after saturation, and a supply of the precursor is such that the reactive surface sites are saturated thereby per cycle. “Chemisorption” refers to chemical saturation adsorption.

The embodiments will be explained with respect to preferred embodiments. However, the present invention is not limited to the preferred embodiments.

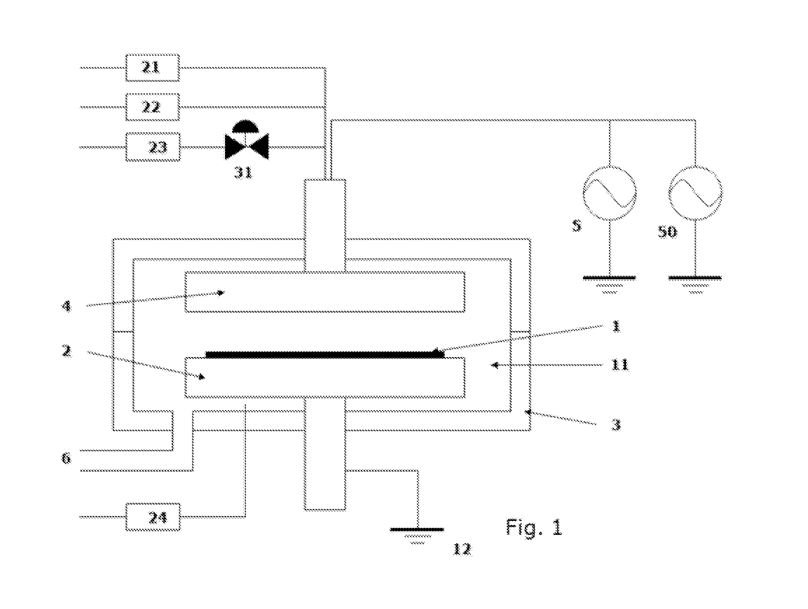

FIG. 1 is a schematic view of a PEALD apparatus, desirably in conjunction with controls programmed to conduct the sequences described below, usable in some embodiments of the present invention. In this figure, by providing a pair of electrically conductive flat-plate electrodes 4, 2 in parallel and facing each other in the interior 11 of a reaction chamber 3, applying HRF power (13.56 MHz or 27 MHz) 5 and LRF power of 5 MHz or less (400 kHz˜500 kHz) 50 to one side, and electrically grounding 12 to the other side, a plasma is excited between the electrodes. A temperature regulator is provided in a lower stage 2 (the lower electrode), and a temperature of a substrate 1 placed thereon is kept constant at a given temperature. The upper electrode 4 serves as a shower plate as well, and reaction gas and rare gas are introduced into the reaction chamber 3 through a gas flow controller 23, a pulse flow control valve 31, and the shower plate. Additionally, in the reaction chamber 3, an exhaust pipe 6 is provided, through which gas in the interior 11 of the reaction chamber 3 is exhausted. Additionally, the reaction chamber is provided with a seal gas flow controller 24 to introduce seal gas into the interior 11 of the reaction chamber 3 (a separation plate for separating a reaction zone and a transfer zone in the interior of the reaction chamber is omitted from this figure).

A skilled artisan will appreciate that the apparatus includes one or more controller(s) (not shown) programmed or otherwise configured to cause the deposition and reactor cleaning processes described elsewhere herein to be conducted. The controller(s) are communicated with the various power sources, heating systems, pumps, robotics and gas flow controllers or valves of the reactor, as will be appreciated by the skilled artisan.

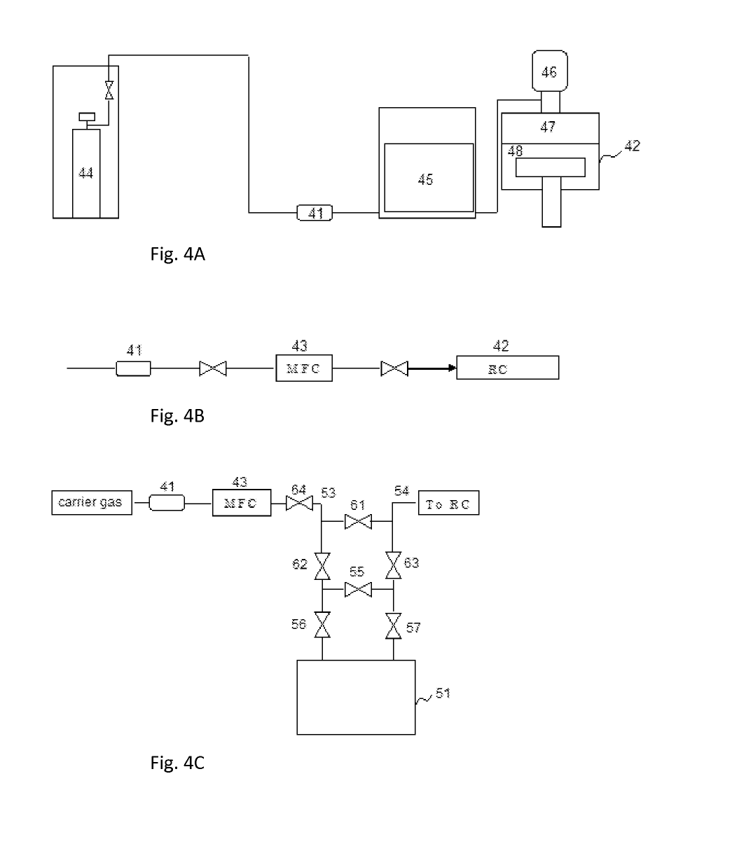

FIG. 4A is a schematic representation of a gas supply system for a reactant gas according to an embodiment of the present invention. In this embodiment, a reaction gas cylinder 44 supplies a reaction gas, and is connected to a gas box 45 installed for a reaction chamber 42 which comprises a reaction space 48 therein and a showerhead 47 to which a remote plasma unit 46 is connected. A purifier 41 is provided on a line connecting the gas cylinder 44 and the gas box 45, in order to purify the reaction gas upstream of the reaction chamber. FIG. 4B is a schematic representation of a gas supply system for a reactant gas according to an embodiment of the present invention. In this embodiment, the purifier 41 is provided upstream of a mass flow controller (MFC) 43 (i.e., the primary side of the MFC). In some embodiments, the gas box 45 in FIG. 4A has the structure illustrated in FIG. 4B where first purifier 41 is installed upstream of the gas box 45, and second purifier 41 is installed upstream of the MFC 43 in the gas box.

FIG. 4C is a schematic representation of a flow-pass system for a precursor according to an embodiment of the present invention. In this embodiment, the flow-pass system comprises a bottle 51 containing a liquid precursor, which is provided between a carrier gas source and a reaction chamber. The MFC 43 is provided between the carrier gas source and the bottle 51, and the purifier 41 is between the MFC 43 and the carrier gas source. In this system, a liquid precursor is vaporized in a bottle 51, a carrier gas is introduced into the bottle 51 through a line 53 via the purifier 41, the MFC 43, a valve 64, valve 62, and valve 56 in this order. The carrier gas flows out from the bottle 51 with the vaporized precursor to the reaction chamber through a line 54 via a valve 57 and valve 63. When the carrier gas bypasses the bottle 51, the carrier gas flows to the reaction chamber via the purifier 41, the MFC 43, the valve 64, valve 62, valve 55, and valve 63. The valves 62, 61, and 63 are additional valves. No MFC is provided on the line 54. A dilution gas can be fed to the reaction space in a manner substantially similar to that for the reactant gas. Further, more than one purifier can be installed in series.

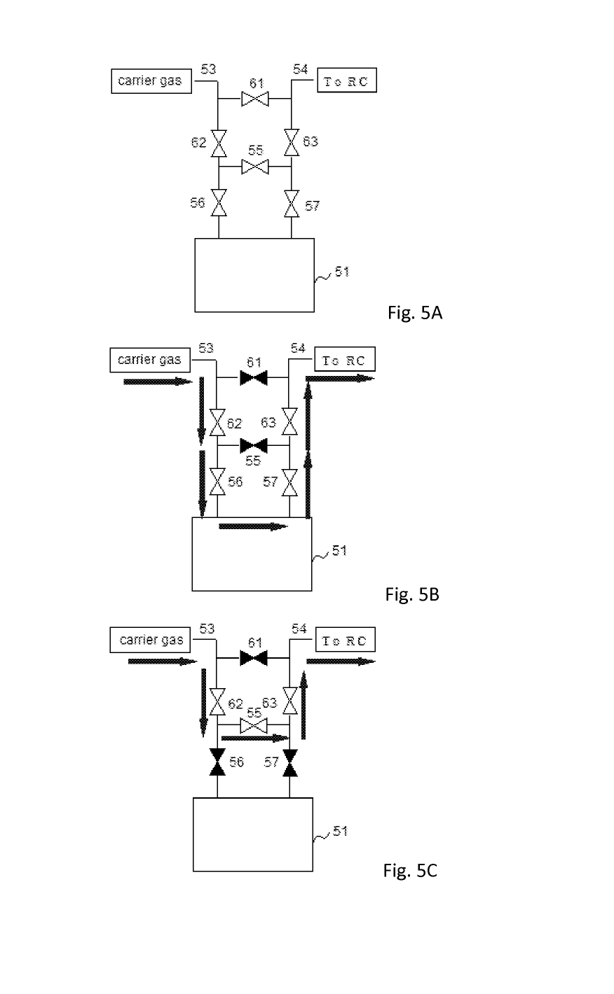

FIG. 5A is a schematic representation of a flow-pass system for a liquid material usable in an embodiment of the present invention, wherein no MFC is provided or a MFC is omitted for the purpose of explaining the flow-pass system. FIG. 5B is a schematic representation of the flow-pass system when a carrier gas carries a vaporized precursor from a bottle and flows with the precursor to a reaction chamber. FIG. 5C is a schematic representation of the flow-pass system when a carrier gas bypasses the bottle and flows without the precursor to the reaction chamber. In this system, a liquid precursor is vaporized in the bottle 51, a carrier gas is introduced into the bottle 51 through a line 53 via valves 56, 62 since valves 55, 61 are closed. The carrier gas carries the vaporized precursor and flows out together from the bottle 51 through a line 54 via valves 57, 63 as illustrated in FIG. 5B. However, when the valve 55 is open (also the valves 62, 63 are open), and the valves 56, 57 are closed, only the carrier gas flows through the lines 53, 54 as illustrated in FIG. 5C. By switching a precursor and a carrier gas flow, a inflow rate and an RC pressure can substantially be constant and an RC pressure is easily controlled by an automatic pressure controller (not shown).

A skilled artisan will appreciate that the apparatus includes one or more controller(s) (not shown) programmed or otherwise configured to cause the deposition and reactor cleaning processes described elsewhere herein to be conducted. The controller(s) are communicated with the various power sources, heating systems, pumps, robotics and gas flow controllers or valves of the reactor, as will be appreciated by the skilled artisan.

The present invention is further explained with reference to working examples below. However, the examples are not intended to limit the present invention. In the examples where conditions and/or structures are not specified, the skilled artisan in the art can readily provide such conditions and/or structures, in view of the present disclosure, as a matter of routine experimentation. Also, the numbers applied in the specific examples can be modified by a range of at least ±50% in some embodiments, and the numbers are approximate.

### EXAMPLES

Metal-containing films were deposited on substrates having patterns (aspect ratio: 2:1) under common conditions shown in Table 2 or 3 below using the process sequence illustrated in FIG. 2 (continuous reactant flow) or FIG. 3 (pulsed reactant flow), and using the apparatus illustrated in FIG. 1. A precursor was fed to the reaction chamber using the flow-pass system illustrated in FIGS. 5A to 5C. For purifying gases, a Gas Clean ( [symbol] [symbol] ) ST Purifier assembly (by Pall Corporation) was used, which was designed to remove contamination from many process gases, wherein sub ppb level purification was capable at designed flow rates of up to 5 slm while providing 0.003 μm filtration, and according to the technical information, it was capable of reducing impurities H₂O, CO₂, O₂, and CO to less than 1 ppb from argon, nitrogen, and hydrogen. The purifiers were installed as illustrated in FIGS. 4A to 4C. For purifying gases, the carrier gas, dilution gas, and reactant gas passed through the purifiers, respectively.

TABLE 2
(continuous reactant gas flow)
Conditions

| | |
|---|---|
| Pressure | 400 Pa |
| Flow rate of reactant (continuous) | changed according to the |
| | target concentration |
| Dilution gas (rare gas) | Ar |
| Flow rate of dilution gas | 500 sccm (continuous) |
| Flow rate of precursor (including carrier gas) | 2010 sccm (the carrier gas |
| | was continuous) |
| Seal gas | Ar, 200 sccm (continuous) |
| Precursor pulse (supply time of the gas) | 1 sec |
| Purge upon the precursor pulse | 1 sec |
| RF power (13.56 MHz) for a 300-mm wafer | 100 W |
| RF power pulse | 5 sec |
| Purge upon the RF power pulse | 1 sec |
| Thickness of film | 15 nm |

TABLE 3
(pulsed reactant gas flow)
Conditions

| | |
|---|---|
| Pressure | 400 Pa |
| Flow rate of reactant (pulsed) | changed according to the |
| | target concentration |
| Dilution gas (rare gas) | Ar |
| Flow rate of dilution gas | 500 sccm (continuous) |
| Flow rate of precursor (including carrier gas) | 2010 sccm (the carrier gas |
| | was continuous) |
| Seal gas | Ar, 200 sccm (continuous) |
| Precursor pulse (supply time of the gas) | 1 sec |
| Purge upon the precursor pulse | 1 sec |
| Reactant pulse (supply time of the reactant) | 5 sec |
| RF power (13.56 MHz) for a 300-mm wafer | 100 W (with reactant flow) |
| RF power pulse | 5 sec |
| Purge upon the RF power pulse | 5 sec |
| Thickness of film | 15 nm |

### Examples 1 to 15

A metal oxide film was formed on a substrate (0300 mm) by PEALD under conditions shown in Table 4 below in addition to the above-described common conditions. The value (%) of O₂ concentration (i.e., the partial pressure of O₂) was rounded off to a natural number (no decimal place) (in some embodiments, the value is rounded off to one or two decimal places). Also, the O₂ concentration when pulsed represents the concentration while being fed, not throughout the entire cycle. The growth rate per cycle (GPC) of each film was determined, and the obtained metal oxide film was evaluated in terms of the number of particles having a size of 0.1 μm or greater, and chemical resistance (wet etch rate in DHF at 100:1 as compared with thermal oxide film). The results are shown in Table 5 below.

TABLE 4

| | | | O2 | | |
|---|---|---|---|---|---|
| | | Temp | Concentration | | O2 |
| Ex. | Precursor | (° C.) | (%) | Purifier | Flow |
| 1* | Tetrakis(dimethyl-amino)-Zr | 200 | 17 | No | Continuous |
| 2* | Tetrakis(dimethyl-amino)-Zr | 200 | 17 | No | Continuous |
| 3* | Tetrakis(dimethyl-amino)-Zr | 200 | 17 | No | Pulsed |
| 4* | Tris(dimethyl-amino)- | 200 | 17 | No | Pulsed |
| | cyclopentadienyl-Zr | | | | |
| 5* | Tris(dimethyl-amino)- | 200 | 17 | No | Continuous |
| | cyclopentadienyl-Zr | | | | |
| 6 | Tris(dimethyl-amino)- | 200 | 17 | Yes | Continuous |
| | cyclopentadienyl-Zr | | | | |
| 7 | Tris(dimethyl-amino)- | 200 | 4 | No | Continuous |
| | cyclopentadienyl-Zr | | | | |
| 8 | Tris(dimethyl-amino)- | 200 | 4 | Yes | Continuous |
| | cyclopentadienyl-Zr | | | | |
| 9 | Tris(dimethyl-amino)- | 200 | 11 | No | Continuous |
| | cyclopentadienyl-Zr | | | | |
| 10* | Tetrakis (dimethyl-amino)-V | 250 | 17 | No | Pulsed |
| 11* | Tetrakis(dimethyl-amio)-V | 250 | 17 | No | Continuous |
| 12 | Tetrakis(dimethyl-amino)-V | 250 | 17 | Yes | Continuous |
| 13 | Tetrakis(dimethyl-amino)-V | 250 | 4 | No | Continuous |
| 14 | Tris(dimethyl-amino)- | 200 | 3 | Yes | Continuous |
| | cyclopentadienyl-Hf | | | | |
| 15 | Tris(dimethyl-amino)- | 200 | 19 | Yes | Continuous |
| | cyclopentadienyl-Hf | | | | |

*denotes comparative examples.

TABLE 5

| | | | 100:1 |
|---|---|---|---|
| | | | DHF |
| | ≧0.1 μm | GPC | WERR of |
| Ex. | Particle(ea) | (nm/cycle) | TOX |
| 1* | 23450 | 0.05 | <0.1 |
| 2* | 25200 | 0.055 | <0.1 |
| 3* | 13 | 0.05 | <0.1 |
| 4* | 15 | 0.09 | <0.1 |
| 5* | 9875 | 0.09 | <0.1 |
| 6 | 20 | 0.09 | <0.1 |
| 7 | 12 | 0.1 | <0.1 |
| 8 | 9 | 0.1 | <0.1 |
| 9 | 15 | 0.09 | <0.1 |
| 10* | 8 | 0.1 | <0.1 |
| 11* | 4267 | 0.1 | <0.1 |
| 12 | 16 | 0.1 | <0.1 |
| 13 | 10 | 0.11 | <0.1 |
| 14 | 13 | 0.09 | <0.1 |
| 15 | 15 | 0.09 | ≦0.1 |

*denotes comparative examples.

As shown in Table 5, when the process sequence of FIG. 3 where the reactant gas was fed in pulses was employed as in Examples 3, 4, and 10, despite the fact that no particle-reduction step was performed, the number of particles attached to the surface of the processed substrate was less than 20. However, in the process sequence of FIG. 2 where the reactant gas was continuously fed to the reaction chamber, when neither controlling the partial pressure of the reactant at 15% or less (preferably less than 12%) nor purifying the gases was conducted as a particle-reduction step as in Examples 1, 2, 5, and 11, the number of particles attached to the surface of the processed substrate was about five thousand or more. That is, the precursors and the reactant gas used in the examples were highly reactive to each other. The number of particles was higher when the reactive group of the precursor had a lower molecular size as in Examples 1 and 2 (—N(CH₃)₂), than that when reactive group of the precursor had a higher molecular size as in Example 5 (—O₅H₄), and also, the number of particles was higher when the metal contained in the precursor was more easily oxidized (having lower standard electrode potential E°) as in Examples 1 and 2 (Zr; E°=−1.45), than that when the metal contained in the precursor was less easily oxidized (having higher standard electrode potential E°) as in Example 11 (V; E°=−1.13). Incidentally, in Examples 1 and 2, although the O₂ concentration (partial pressure) was the same, the flow rate of the carrier gas in Example 2 was 10% higher than that in Example 1 (thus, the flow rate of the reactant gas in Example 2 was proportionally higher than that in Example 1), indicating that although the flow rates of the precursor and reactant gas were different, when the partial pressures of the reactant gas were equivalent, the number of particles attached to the surface of the processed substrate were not significantly changed.

In contrast to the above comparative Examples, in the process sequence of FIG. 2 where the reactant gas was continuously fed to the reaction chamber, when at least either controlling the partial pressure of the reactant at 15% or less (preferably less than 12%) or purifying the gases was conducted as a particle-reduction step as in Examples 6 to 9 and 12 to 15, the number of particles attached to the surface of the processed substrate was remarkably lowered from thousands to 20 or less. Further, when both controlling the partial pressure of the reactant at 15% or less (preferably less than 12%) and purifying the gases were conducted as particle-reduction steps as in Example 8, the number of particles attached to the surface of the processed substrate was lower than only one of controlling the partial pressure of the reactant at 15% or less (preferably less than 12%) and purifying the gases was conducted as particle-reduction steps as in Examples 7 and 9. Additionally, the particle-reduction step did not affect chemical resistance.

### Examples 16 to 22

A metal nitride film was formed on a substrate (0300 mm) by PEALD under conditions shown in Table 6 below in addition to the above-described common conditions. The growth rate per cycle (GPC) of each film was determined, and the obtained metal oxide film was evaluated in terms of the number of particles having a size of 0.1 μm or greater. The results are shown in Table 7 below.

TABLE 6

| | | | N₂/H₂¹⁾ | | |
|---|---|---|---|---|---|
| | | Temp | Concentration | | N₂/H₂ |
| Ex. | Precursor | (° C.) | (%) | Purifier | Flow |
| 16* | Tetrakis(dimethyl-amino)-Zr | 200 | 17 | No | Continuous |
| 17* | Tetrakis(dimethyl-amino)-Zr | 200 | 17 | No | Continuous |
| 18* | Tris(dimethyl-amino)- | 200 | 17 | No | Pulsed |
| | cyclopentadienyl-Zr | | | | |
| 19* | Tris(dimethyl-amino)- | 200 | 17 | No | Continuous |
| | cyclopentadienyl-Zr | | | | |
| 20 | Tris(dimethyl-amino)- | 200 | 17 | Yes | Continuous |
| | cyclopentadienyl-Zr | | | | |
| 21 | Tris(dimethyl-amino)- | 200 | 4 | No | Continuous |
| | cyclopentadienyl-Zr | | | | |
| 22 | Tris(dimethyl-amino)- | 200 | 19 | Yes | Continuous |
| | cyclopentadienyl-Hf | | | | |

*denotes comparative examples.
¹⁾a flow ratio was 17% (N₂ = 100 sccm; H₂ = 600 sccm)

TABLE 7

| | ≧0.1 μm | GPC |
|---|---|---|
| Ex. | Particle(ea) | (nm/cycle) |
| 16* | 23450 | 0.05 |
| 17* | 25200 | 0.055 |
| 18* | 15 | 0.09 |
| 19* | 9875 | 0.09 |
| 20 | 20 | 0.09 |
| 21 | 12 | 0.1 |
| 22 | 16 | 0.8 |

*denotes comparative examples.

As shown in Table 7, when the process sequence of FIG. 3 where the reactant gas was fed in pulses was employed as in Example 18, despite the fact that no particle-reduction step was performed, the number of particles attached to the surface of the processed substrate was less than 20. However, in the process sequence of FIG. 2 where the reactant gas was continuously fed to the reaction chamber, when neither controlling the partial pressure of the reactant at 15% or less (preferably less than 5%) nor purifying the gases was conducted as a particle-reduction step as in Examples 16, 17, and 19, the number of particles attached to the surface of the processed substrate was about ten thousand or more. That is, the precursors and the reactant gas used in the examples were highly reactive to each other. The number of particles was higher when the reactive group of the precursor had a lower molecular size as in Examples 16 and 17 (—N(CH₃)₂), than that when reactive group of the precursor had a higher molecular size as in Example 19 (—C₅H₄).

In contrast, in the process sequence of FIG. 2 where the reactant gas was continuously fed to the reaction chamber, when at least either controlling the partial pressure of the reactant at 15% or less (preferably less than 5%) or purifying the gases was conducted as a particle-reduction step as in Examples 20 to 22, the number of particles attached to the surface of the processed substrate was remarkably lowered from thousands to 20 or less.

It will be understood by those of skill in the art that numerous and various modifications can be made without departing from the spirit of the present invention. Therefore, it should be clearly understood that the forms of the present invention are illustrative only and are not intended to limit the scope of the present invention.

We/I claim:

1. A method for forming a metal oxide or nitride film on a substrate by plasma-enhanced atomic layer deposition (PEALD), comprising:
(i) introducing an amino-based metal precursor in a pulse to a reaction space where a substrate is placed, using a carrier gas;
(ii) continuously introducing a reactant gas to the reaction space;
(iii) applying RF power in a pulse to the reaction space wherein the pulse of the precursor and the pulse of RF power do not overlap; and
(iv) repeating steps (i) to (iii) to deposit a metal oxide or nitride film on the substrate,
wherein at least one particle-reduction step is conducted in step (i) and/or step (ii), said at least one particle-reduction step being selected from step (a) comprising passing the carrier gas through a purifier for reducing impurities contained in the carrier gas, and then mixing the carrier gas with a gas of the precursor upstream of the reaction space in step (i); and step (b) introducing the reactant gas to the reaction space in step (ii) at a flow rate such that a partial pressure of the reactant gas relative to the total gas flow provided in the reaction space is 15% or less.

2. The method according to claim 1, wherein step (a) is conducted as the at least one particle-reduction step wherein the impurities include H₂O, and O₂, CO₂, and/or CO if any.

3. The method according to claim 2, wherein the impurities contained in the carrier gas are reduced to 10 ppb or less.

4. The method according to claim 1, wherein step (ii) further comprises passing the reactant gas through a purifier for reducing impurities contained in the reactant gas before introducing the reactant gas to the reaction space.

5. The method according to claim 4, wherein the reactant gas passes through a mass flow controller, wherein the purifier is provided upstream of the mass flow controller.

6. The method according to claim 4, wherein step (ii) further comprises introducing to the reaction space a dilution gas for diluting the reaction gas, wherein the dilution gas passes through a purifier for reducing impurities contained in the dilution gas before entering into the reaction space.

7. The method according to claim 1, wherein step (b) is conducted as the at least one particle-reduction step.

8. The method according to claim 1, wherein both steps (a) and (b) are conducted as the at least one particle-reduction step.

9. The method according to claim 1, wherein the carrier gas is Ar and/or He.

10. The method according to claim 1, wherein the reactant gas is at least one selected from the group consisting of O₂, N₂O, CO₂, NxOyHz, and CxOyHz wherein x, y, and z are each an integer, for forming a metal oxide film on the substrate.

11. The method according to claim 1, wherein the reactant gas is at least one selected from the group consisting of NH₃, N₂/H₂, N₂, H₂, and CxHyNz wherein x, y, and z are each an integer with the proviso that if x is zero, y and z are not zero, and if z is zero, x and y are not zero, for forming a metal nitride film on the substrate.

12. The method according to claim 1, wherein the amino-based metal precursor is at least one selected from the group consisting of: 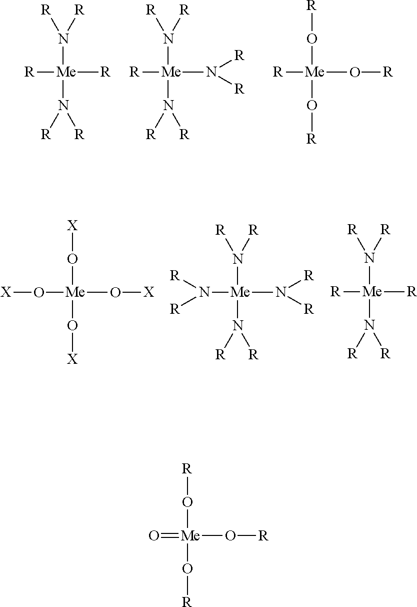
wherein R is independently H, CxHy, CxHyOz, CS, or CO (wherein x, y, and z are each an integer), X is independently H, CxHy, or CxHyOz (wherein x, y, and z are each an integer), and Me is a metal.

13. The method according to claim 1, wherein the metal is a transition element.

14. The method according to claim 13, wherein the metal is selected from the groups consisting of Zr, Ti, Hf, Ta, Ir, V, and Ce.

15. The method according to claim 1, wherein the precursor is tris(dimethyl-amido)-cyclopentadienyl-Zr, tris(dimethyl-amino)-cyclopentadienyl-Hf, and/or tetrakis(dimethyl-amino)-V.

16. The method according to claim 1, wherein the reaction space is controlled at a temperature of 0° C. to 250° C.

17. The method according to claim 1, wherein the gas of the precursor before being mixed with the carrier gas is a vapor of the precursor having a pressure of 0.1 to 3 Torr.

18. The method according to claim 1, wherein the carrier gas is continuously introduced to the reaction space wherein the precursor is mixed with the carrier gas in a pulse in step (i).

19. The method according to claim 6, wherein the dilution gas is continuously introduced to the reaction space.

20. The method according to claim 1, wherein the number of particles having a size of 0.1 μm or more present on the metal oxide or nitride film on the substrate is less than 500.
